(19) United States
(12) Patent Application Publication
(10) Pub. No.: US 2025/0150058 A1
(43) Pub. Date: May 8, 2025

(54) BULK ACOUSTIC WAVE STRUCTURES WITH VERTICALLY STACKED RESONATORS

(71) Applicant: Qorvo US, Inc., Greensboro, NC (US)

(72) Inventors: Eloi Guerrero, Terrassa (ES); Alfred Raul Gimenez Bonastre, Longwood, FL (US); Seyed Amin Sandoughsaz Zardini, Sanford, FL (US); Yazid Yusuf, Orlando, FL (US); Paul Michael Stokes, Orlando, FL (US)

(21) Appl. No.: 18/933,573

(22) Filed: Oct. 31, 2024

Related U.S. Application Data
(60) Provisional application No. 63/598,670, filed on Nov. 14, 2023.

(51) Int. Cl. H03H 9/58; H03H 3/02

(52) U.S. Cl. CPC H03H 9/585; H03H 3/02; H03H 9/589

(57) ABSTRACT

A radio frequency (RF) filtering circuit. The RF circuit includes a first acoustic resonator disposed over a substrate; a second acoustic resonator disposed over the first acoustic resonator; and a via structure disposed between the first acoustic resonator and the second acoustic resonator, in contact with the first acoustic resonator and the second acoustic resonator. The first acoustic resonator and the second acoustic resonator are conductively connected to each other through the via structure.

### RELATED APPLICATIONS

This application claims priority to U.S. Provisional Patent Application No. 63/598,670 filed Nov. 14, 2023, which is incorporated by reference herein in its entirety.

### FIELD OF THE INVENTION

This disclosure relates to bulk acoustic wave (BAW) structures. In particular, this disclosure relates to BAW structures with vertically stacked BAW resonators, and method for forming the BAW structures.

### BACKGROUND

Acoustic filters, e.g., particularly Bulk Acoustic Wave (BAW) resonators or BAW filters, are used in high-frequency communication applications such as 3^{rd} Generation (3G), 4^{th} Generation (4G), and 5^{th} Generation (5G) wireless devices. In particular, a BAW filter is often employed to provide a flat passband, steep filter skirts, and squared shoulders at the upper and lower ends of the passband, and provide excellent rejection outside of the passband in a filter network. BAW filters also have relatively low insertion loss, tend to decrease in size as the frequency of operation increases, and are relatively stable over wide temperature ranges. These wireless devices often support various communication means such as cellular, wireless fidelity (Wi-Fi), Bluetooth, and/or near field communications, and accordingly, high performance of the BAW filters are needed.

BAW filters (e.g., BAW die, BAW filter die, etc.), or other BAW structure, are widely used in filtering signals in communication (e.g., 5G networks) in electronic devices. As electronic devices continue to scale down, BAW filters, especially those operating at certain frequencies (e.g., greater than 5 GHZ), may require smaller resonator areas. However, reducing resonator areas requires cascading multiple resonators in series to handle high power levels, thereby adding more resistance and/or electrical loss. An approach to alleviate the electrical loss is making the materials with high electrical conductivity (e.g., aluminum copper (AlCu)) thicker, but doing so may result in increased acoustic losses since these materials are typically acoustically lossy and larger thicknesses cause larger fractions of energy (stress/strain) to be contained in these layers.

Therefore, there is a need for BAW structures of smaller resonator areas with high conductivity and low loss.

### SUMMARY

Aspects of the disclosure include a radio frequency (RF) filtering circuit. The RF circuit includes a first acoustic resonator disposed over a substrate; a second acoustic resonator disposed over the first acoustic resonator; and a via structure disposed between the first acoustic resonator and the second acoustic resonator, in contact with the first acoustic resonator and the second acoustic resonator. The first acoustic resonator and the second acoustic resonator are conductively connected to each other through the via structure.

In some embodiments, the first acoustic resonator includes: a first piezoelectric layer, a first electrode disposed over the first piezoelectric layer, a second electrode disposed under the first piezoelectric layer, a first insulating layer over the first electrode, a second insulating layer under the second electrode, a first reflector structure over the first insulating layer, and a second reflector structure under the second insulating layer. In some embodiments, the second acoustic resonator includes a second piezoelectric layer, a first electrode disposed over the second piezoelectric layer, a second electrode disposed under the second piezoelectric layer, a first insulating layer over the first electrode, a second insulating layer under the second electrode, a first reflector structure over the first insulating layer, and a second reflector structure under the second insulating layer.

In some embodiments, the first reflector structure includes a first conductive bridge structure conductively connected to a peripheral area of the first electrode; and the second reflector structure includes a second conductive bridge structure conductively connected to a peripheral area of the second electrode.

In some embodiments, the first reflector structure and the second reflector structure each includes a stack of alternating high-acoustic-impedance metal layers and low-acoustic-impedance metal layers.

In some embodiments, the high-acoustic-impedance metal layers include tungsten, and the low-acoustic-impedance metal layers include aluminum copper.

In some embodiments, the via structure is in contact with the second reflector structure of the first acoustic resonator and the first reflector structure of the second acoustic resonator.

In some embodiments, the via structure is disposed in an insulating spacer between the second reflector structure of the first acoustic resonator and the first reflector structure of the second acoustic resonator, wherein a thickness of the insulating spacer is between about 3 μm and about 5 μm.

In some embodiments, the via structure includes copper.

In some embodiments, a vertical projection of the via structure is overlapped with a vertical projection of at least one of the first acoustic resonator or the second acoustic resonator.

In some embodiments, a vertical projection of the via structure is located outside a vertical projection of the first acoustic resonator or the second acoustic resonator.

In some embodiments, the first acoustic resonator and the second acoustic resonator are connected in series.

In some embodiments, the first acoustic resonator and the second acoustic resonator are each a series resonator.

In some embodiments, the first acoustic resonator is a series resonator, and the second acoustic resonator is a shunt resonator, the first reflector structure of the second acoustic resonator is connected to ground.

In some embodiments, the RF filtering circuit further includes a connection structure in contact with the first reflector structure of the second acoustic resonator and the second reflector of the first acoustic resonator.

In some embodiments, the first acoustic resonator and the second acoustic resonator are connected in antiparallel, the first reflector structure of the second acoustic resonator is connected to ground.

In some embodiments, the connection structure includes a first stack of alternating high-acoustic-impedance metal layers and low-acoustic-impedance metal layers, a second stack of the alternating high-acoustic-impedance metal layers and low-acoustic-impedance metal layers over the first stack, and a second via structure in contact with the first stack and the second stack.

In some embodiments, the RF filtering circuit further includes a third acoustic resonator on a same level as the first acoustic resonator. The third acoustic resonator includes a third piezoelectric layer leveling with and in contact with the first piezoelectric layer, and a first reflector structure leveling with and in contact with the first reflector structure of the first acoustic resonator. In some embodiments, the RF filtering circuit further includes a fourth acoustic resonator on a same level as the second acoustic resonator. The fourth acoustic resonator includes a fourth piezoelectric layer leveling with and in contact with the second piezoelectric layer, a first reflector structure leveling with and in contact with the first reflector structure of the second acoustic resonator, and a second reflector structure leveling with and in contact with the second reflector structure of the second acoustic resonator. The first reflector structure of the second acoustic resonator is connected to ground.

In some embodiments, the first acoustic resonator and the third acoustic resonator are series resonators conductively connected in series with each other such that the first electrode of the first acoustic resonator is conductively connected to a first electrode of the third acoustic resonator. In some embodiments, the second acoustic resonator and the fourth acoustic resonator are shunt resonators conductively connected in parallel with each other between ground and a middle point between the first acoustic resonator and the third acoustic resonator such that the first electrode of the second acoustic resonator is conductively connected to a first electrode of the fourth acoustic resonator, and the second electrode of the second acoustic resonator is conductively connected to a second electrode of the fourth acoustic resonator.

In some embodiments, the RF filtering circuit further includes a third acoustic resonator on a same level as the first acoustic resonator. The third acoustic resonator includes a third piezoelectric layer leveling with and in contact with the first piezoelectric layer, and a first reflector structure leveling with and in contact with the first reflector structure of the first acoustic resonator. In some embodiments, the RF filtering circuit further includes a fourth acoustic resonator on a same level as the second acoustic resonator. The fourth acoustic resonator includes a fourth piezoelectric layer leveling with and in contact with the second piezoelectric layer, a first reflector structure leveling with and in contact with the first reflector structure of the second acoustic resonator, and a second reflector structure leveling with and in contact with the second reflector structure of the second acoustic resonator. The second reflector structure of the fourth acoustic resonator is conductively connected to the second reflector structure of the third acoustic resonator.

In some embodiments, the first acoustic resonator and the third acoustic resonator are series resonators conductively connected in series with each other such that the first electrode of the first acoustic resonator is conductively connected to a first electrode of the third acoustic resonator. In some embodiments, the second acoustic resonator is a shunt resonator conductively connected to both the first acoustic resonator and the third acoustic resonator such that the second electrode of the second acoustic resonator is conductively connected to the first electrode of the first acoustic resonator and the first electrode of the third acoustic resonator. In some embodiments, the fourth acoustic resonator is another shunt resonator conductively connected to the third acoustic resonator such that the second electrode of the fourth acoustic resonator is conductively connected to the second electrode of the third acoustic resonator.

Another aspect of the present disclosure provides a method for forming a radio frequency (RF) circuit. The RF circuit includes: forming a first wafer comprising a first acoustic resonator over a first substrate and a first initial via structure conductively connected to the first acoustic resonator; forming a second wafer comprising a second acoustic resonator over a second substrate and a second initial via structure conductively connected to the first acoustic resonator; and bonding the first wafer and the second wafer in a face-to-face manner such that the first initial via structure is in contact with the second initial via structure to form a via structure.

In some embodiments, the method further includes removing the first substrate.

In some embodiments, the forming of the first acoustic resonator and the second acoustic resonator each includes: forming a first reflector structure over the respective substrate; forming a first insulating layer over the first reflector structure; forming a first electrode over the first insulating layer; forming a piezoelectric layer over the first electrode; forming a second electrode over the piezoelectric layer; forming a second insulating layer over the second electrode; and forming a second reflector structure over the second insulating layer.

In some embodiments, the forming of the first reflector structure and the second reflector structure each includes forming a stack of alternating high-acoustic-impedance metal layers and low-acoustic impedance-metal layers that are conductively connected to the respective electrode.

In some embodiments, the forming of the first initial via structure and the second initial via structure each includes: depositing a conductive material layer on the second reflector structure of the respective acoustic resonator; patterning the conductive material layer to form a conductive layer; depositing a dielectric layer on the second reflector structure of the respective acoustic resonator; and planarizing the dielectric layer to expose the conductive layer.

In some embodiments, the method further includes forming an initial connection structure over the respective substrate. The forming of the initial connection structure includes forming a stack structure in a same process of the stack of the first reflector structure of the second reflector structure; depositing another conductive material layer over the stack structure in a same process of the conductive material layer; and patterning the other conductive material layer to form a conductive portion.

Another aspect of the present disclosure provides a method for forming a radio frequency (RF) circuit. The method includes forming a first acoustic resonator over a substrate; forming a via structure over and conductively connected to the first acoustic resonator; and forming a second acoustic resonator over and conductively connected to the via structure.

In some embodiments, the forming of the first acoustic resonator and the second acoustic resonator each includes: forming a first reflector structure over the substrate; forming a first insulating layer over the first reflector structure; forming a first electrode over the first insulating layer; forming a piezoelectric layer over the first electrode; forming a second electrode over the piezoelectric layer; forming a second insulating layer over the second electrode; and forming a second reflector structure over the second insulating layer.

In some embodiments, the forming of the via structure includes depositing a conductive material layer on the second reflector structure of the first acoustic resonator; patterning the conductive material layer to form a conductive layer; depositing a dielectric layer on the second reflector structure of the respective acoustic resonator; and planarizing the dielectric layer to expose the conductive layer.

In some embodiments, the forming of the second acoustic resonator includes forming the first reflector structure of the second acoustic resonator over the dielectric layer such that the first reflector structure is in contact with the via structure.

In some embodiments, the forming of the first reflector structure and the second reflector structure each includes forming a stack of alternating high-acoustic-impedance metal layers and low-acoustic impedance-metal layers that are conductively connected to the respective electrode.

In some embodiments, the method further includes forming a connection structure over the substrate. The forming of the connection structure includes: forming a stack structure in a same process of the stack of the first reflector structure of the second reflector structure; depositing another conductive material layer over the stack structure in a same process of the conductive material layer; and patterning the other conductive material layer.

### BRIEF DESCRIPTION OF THE DRAWINGS

FIG. 1A illustrates an exemplary BAW resonator, according to embodiments of the present disclosure.

FIG. 1B illustrates an exemplary connection structure, according to embodiments of the present disclosure.

FIGS. 2A and 2B each illustrates a circuit diagram of BAW resonators coupled to each other in series, according to embodiments of the present disclosure.

FIGS. 2C-2E each illustrates a cross-sectional view of the circuit diagram shown in FIGS. 2A and 2B, according to embodiments of the present disclosure.

FIG. 3A illustrates a circuit diagram of BAW resonators coupled to each other in antiparallel, according to embodiments of the present disclosure.

FIG. 3B illustrates a cross-sectional view of the circuit diagram shown in FIG. 3A, according to embodiments of the present disclosure.

FIG. 4A illustrates a circuit diagram of BAW resonators coupled to each other in a ladder filter circuit, according to embodiments of the present disclosure.

FIG. 4B illustrates a cross-sectional view of the circuit diagram shown in FIG. 4A, according to embodiments of the present disclosure.

FIG. 5A illustrates another circuit diagram of BAW resonators coupled to each other in a ladder filter circuit, according to embodiments of the present disclosure.

FIG. 5B illustrates a cross-sectional view of the circuit diagram shown in FIG. 5A, according to embodiments of the present disclosure.

FIG. 6A illustrates a flowchart of an exemplary fabrication process shown in FIGS. 7A-7F, according to embodiments of the present disclosure.

FIG. 6B illustrates a flowchart of another exemplary fabrication process shown in FIGS. 8A-8C, according to embodiments of the present disclosure.

FIGS. 7A-7F illustrate a fabrication process to form a BAW filter structure, according to embodiments of the present disclosure.

FIGS. 8A-8C illustrate another fabrication process to form a BAW filter structure, according to embodiments of the present disclosure.

### DETAILED DESCRIPTION

The following detailed description is illustrative in nature and is not intended to limit the scope, applicability, or configuration of inventive embodiments disclosed herein in any way. Rather, the following description provides practical examples, and those skilled in the art will recognize that some of the examples may have suitable alternatives. Embodiments will hereinafter be described in conjunction with the appended drawings, which are not to scale (unless so stated), wherein like numerals/letters denote like elements. However, it will be understood that the use of a number to refer to a component in a given drawing is not intended to limit the component in another drawing labeled with the same number. In addition, the use of different numbers to refer to components in different drawings is not intended to indicate that the different numbered components cannot be the same or similar to other numbered components. Examples of constructions, materials, dimensions and fabrication processes are provided for select elements and all other elements employ that which is known by those skilled in the art.

As used herein, the term “about” refers to a given amount of value that may vary based on the particular technology node associated with the semiconductor device. Based on a particular technology node, the term “about” can refer to a given amount of value that varies, for example, within 10-30% of the value (e.g., +10%, +20%, or +20% of that value, or +30%).

As used herein, the term “coupling” refers to combining or joining via electricity, and may be interchangeable with “electrically coupling,” “electrically connected,” “connected,” “conductively coupled,” and/or “conductively connected.”

As used herein, a “top structure” refers to a structure located away from a substrate, and a “bottom structure” refers to a structure located closer to the substrate.

Reference will now be made in greater detail to various embodiments of the subject matter of the present disclosure, some embodiments of which are illustrated in the accompanying drawings.

The existing approach to compose a ladder filter with BAW technology is to distribute the BAW resonators on a surface while maintaining spacing rules dictated by process limitations. The resonators then lie in the same plane and thus, the effort for die area shrinkage has focused on reducing resonator area.

To further shrink die size, embodiments of the present disclosure provide novel ways to couple BAW resonators in a circuit structure in at least two levels, e.g., two planes, to form various circuit configurations. For example, two or more BAW resonators may be coupled in series, parallel, and/or antiparallel. The two or more BAW resonators may further be part of a filter circuit, such as a ladder filter circuit. In some embodiments, in a ladder filter circuit, the series resonators may be located in the same level (e.g., same plane), and the shunt resonators may be located in another level. In various embodiments, the electrical connection between the two BAW resonators in different levels may be facilitated by conductive structures (e.g., via structures and/or connection structures) coupling electrodes of the two BAW resonators. In some embodiments, an insulating layer, e.g., a silicon oxide layer, is disposed between adjacent electrodes of two BAW resonators. The silicon oxide layer has a desired thickness to reduce parasitic capacitive coupling between the two BAW resonators to prevent deterioration on filter bandwidth. The circuit structure of the present disclosure occupies less area in the x-y plane while the impact on the filter bandwidth is minimized. In some embodiments, the BAW resonator may have a conductive bridge structure forming a loop with a respective electrode, reducing the resistance and electrical loss of the BAW resonator.

The two-level circuit structure may be formed in various methods. In some embodiments, the two-level filter structure is formed in a monolithic way by forming the two levels of BAW resonators and any conductive structures in a single wafer. For example, BAW resonators may be formed sequentially (e.g., in the first level and then the second level) to be vertically stacked to each other. In some other embodiments, the two-level filter structure is formed through separately forming BAW resonators and conductive structures in two wafers, and bond the two wafers vertically, e.g., through hybrid bonding, to electrically connect the BAW resonators. In various embodiments, BAW resonators on different levels may be the same or different. For example, depending on the circuit, BAW resonators on different levels may include piezoelectric layers of different thicknesses and/or materials. The BAW resonators on different levels may be formed by separate fabrication processes, e.g., in the same wafer or in different wafers, e.g., to form the same or different piezoelectric layer(s) to meet different design requirement.

The present disclosure provides a BAW ladder filter in which resonators, e.g., BAW resonators, are distributed in two (or more) levels in the thickness direction, separated by an oxide layer to reduce parasitic electromagnetic coupling between the two levels. The present disclosure also provide a via structure between the two BAW levels in which a conductor material connects directly the top reflector of the bottom-level resonator with the bottom reflector of the top-level resonator. The two BAW levels are separated by an oxide layer with vias through the piezoelectric materials of both levels. The present disclosure also provides a connection structure to cascade two series resonators on different levels by directly overlapping them. The present disclosure also provides a connection structure to connect two resonators on different levels in parallel and/or anti-parallel connections. The piezoelectric material on each resonator level does not need be the same, and the acoustic stack of each resonator level does not need be the same, allowing single die solutions for BAW assisted cases in which resonators at very spaced frequencies are required. Further, integrated metal-insulator-metal (MIM) capacitors on both resonator levels allow many configurations such as overlapping capacitors, overlapping a capacitor with a resonator, etc.

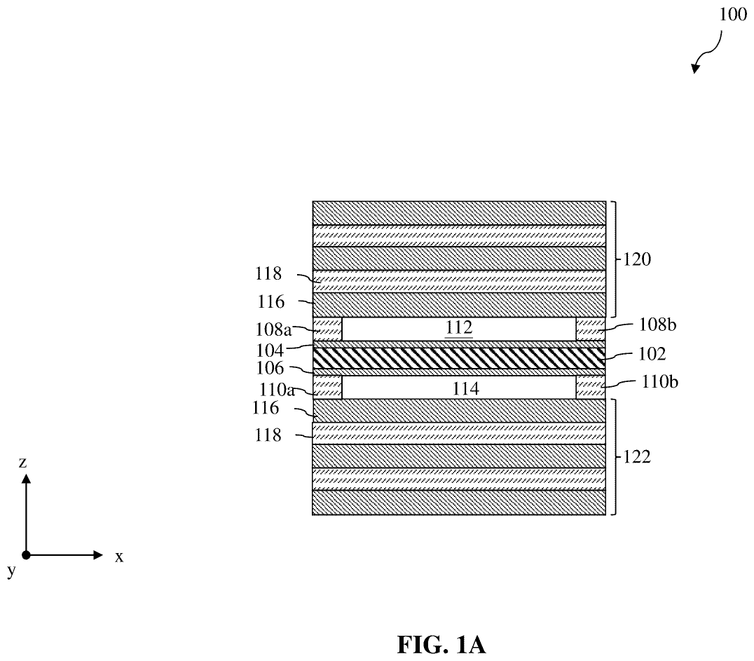

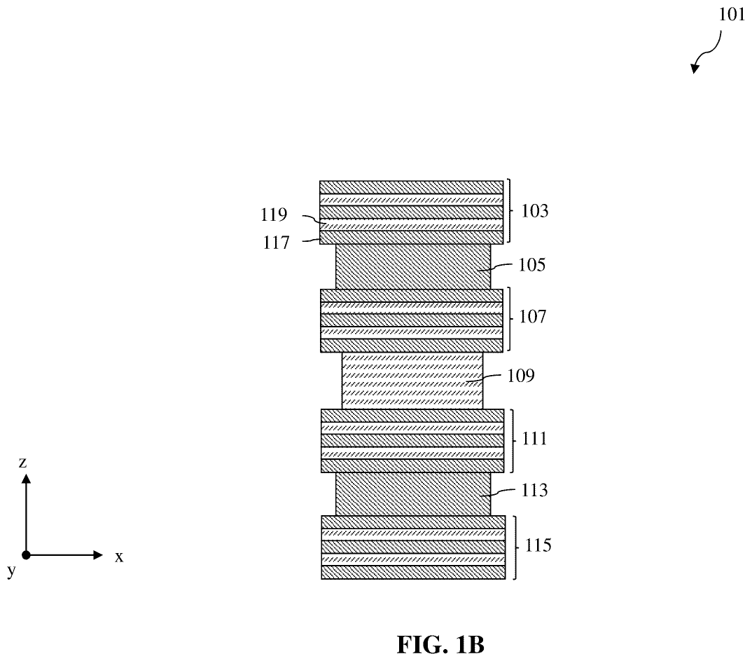

FIG. 1A illustrates a cross-sectional view of a BAW resonator 100, according to embodiments of the present disclosure. BAW resonator 100 may be disposed in a die to form various filter circuits in this disclosure. BAW resonator 100 may include a piezoelectric layer 102, a first electrode 104 (e.g., a top electrode) over piezoelectric layer 102, a second electrode 106 (e.g., a bottom electrode) under piezoelectric layer 102, a first reflector structure 120 (e.g., a top reflector structure) over first electrode 104, a second reflector structure 122 (e.g., a bottom reflector structure) under second electrode 106. BAW resonator 100 may also include a first insulating layer 112 (e.g., a top insulating layer) over first electrode 104, and a second insulating layer 114 (e.g., a bottom insulating layer) under second electrode 106. BAW resonator 100 may further include a first reflector structure 120 (e.g., a top reflector structure) over first insulating layer 112, and a second reflector structure 122 (e.g., a bottom reflector structure) under second insulating layer 114. BAW resonator 100 may include conductive portions 108a and 108b connecting the distal ends of first electrode 104 with first reflector structure 120, and conductive portions 110a and 110b connecting the distal ends of second electrode 106 with second reflector structure 122. In some embodiments, conductive portions 108a and 108b and first reflector structure 120 form a conductive bridge structure connecting one distal end of first electrode 104 and another distal end of first electrode 104, and conductive portions 110a and 110b and second reflector structure 122 form another conductive bridge structure connecting one distal end of second electrode 106 and another distal end of second electrode 106. The conductive bridge structures may reduce the resistance of the electrodes, and thus reduce the electrical loss caused by the electrodes.

First electrode 104 and second electrode 106 may each include one or more suitable conductive materials, and may be a single-layer structure or a multi-layer structure. For example, first electrode 104 and second electrode 106 may each include one or more of copper (Cu), tungsten (W), aluminum copper (AlCu), molybdenum (Mo), and/or platinum (Pt). In some embodiments, first electrode 104 and second electrode 106 may each include tungsten and/or aluminum copper. Piezoelectric layer 102 may include a suitable piezoelectric material such as aluminum nitride (AlN), zinc oxide (ZnO), aluminum scandium nitride (AlScN) and/or other suitable materials. In some embodiments, piezoelectric layer 102 includes AlN. First electrode 104, second electrode 106, and piezoelectric layer 102 may overlap in the z-direction. Although not shown, in some embodiments, piezoelectric layer 102 may extend beyond the overlapping area between first electrode 104 and second electrode 106. For example, piezoelectric layer 102 may extend in the x-y plane. First and second insulating layers 112 and 114 may each include a suitable insulating material such as one or more of silicon oxide, silicon nitride, silicon oxynitride, air gap, etc. In some embodiments, first and second insulating layers 112 and 114 each includes silicon oxide.

First reflector structure 120 may include one or more first stack layers 116 and one or more second stack layers 118 stacking alternatingly in the z-direction. First stack layer 116 and second stack layer 118 may include materials of low resistance (e.g., high conductivity) and different acoustic impedance. In some embodiments, first stack layer 116 includes metal of high acoustic impedance, and second stack layer 118 includes metal of low acoustic impedance. For example, first stack layer 116 includes tungsten and second stack layer 118 includes aluminum copper. In some embodiments, a first stack layer 116 is in contact with first insulating layer 112. Second reflector structure 122 may be similar to first reflector structure 120 and may also include one or more first stack layers 116 and one or more second stack layers 118 stacking alternatingly in the z-direction. In some embodiments, a first stack layer 116 is in contact with second insulating layer 114. In various embodiments, the numbers of first stack layers 116 and second stack layers 118 in first reflector structure 120 and second reflector structure 122 may be the same or different.

Conductive portions 108a, 108b, 110a, and 110b may each include a suitable conductive material such as one or more of copper (Cu), tungsten (W), aluminum copper (AlCu), molybdenum (Mo), and/or platinum (Pt). In some embodiments, conductive portions 108a, 108b, 110a, and 110b may each include aluminum copper. In some embodiments, first reflector structure 120 and conductive portions 108a and 108b may form a conductive bridge structure that is electrically connected to first electrode 104, and second reflector structure 122 and conductive portions 110a and 110b may form a conductive bridge structure that is electrically connected to second electrode 106. The conductive bridges may reduce the electrical resistance and electrical losses caused by the electrodes. BAW resonators with conductive bridge structures has been described in U.S. Pat. No. 11,528,007 B2, which is incorporated herein in its entirety.

FIG. 1B illustrates a connection structure 101, according to embodiments of the present disclosure. Connection structure 101 may be used to connect different parts of a die to form various circuits, such as electrodes of stacking BAW resonators, signal input/output, etc. In some embodiments, connection structure 101 extends through a die in the thickness direction (e.g., z-direction). Connection structure 101 may include one or more stack structures, e.g., 103, 107, 111, and 115. Each of stack structures 103, 107, 111, and 115 may include one or more first stack layers 117 and one or more second stack layers 119 stacking alternatingly in the z-direction. In some embodiments, first stack layer 117 includes tungsten and second stack layer 119 includes aluminum copper. In some embodiments, two adjacent stack structures in a connection structure 101, e.g., 103 and 107, 107 and 111, and 111 an d115, may be connected by a respective via structure. For example, stack structures 103 and 107 may be connected by a via structure 105, stack structures 107 and 111 may be connected by a via structure 109, and stack structures 111 and 115 may be connected by a via structure 113. Via structures 105, 109, and 113 may each include a suitable conductive material such as one or more of copper (Cu), tungsten (W), aluminum copper (AlCu), molybdenum (Mo), and/or platinum (Pt). In some embodiments, via structures 105 and 113 (e.g., at the ends of connection structure 101) each includes tungsten, and via structure 109 (e.g., at the center of connection structure 101) includes copper, e.g., when via structure 109 is formed by hybrid bonding. In various embodiments, the materials of the stack structures (e.g., 103, 107, 111, and 115) and the via structures (e.g., 105, 109, and 113) may be dependent on or the same as the material used to form parts of a BAW resonator on the same level. For example, a stack structure may have the same structures and be formed in the same fabrication process as a reflector structure on the same level.

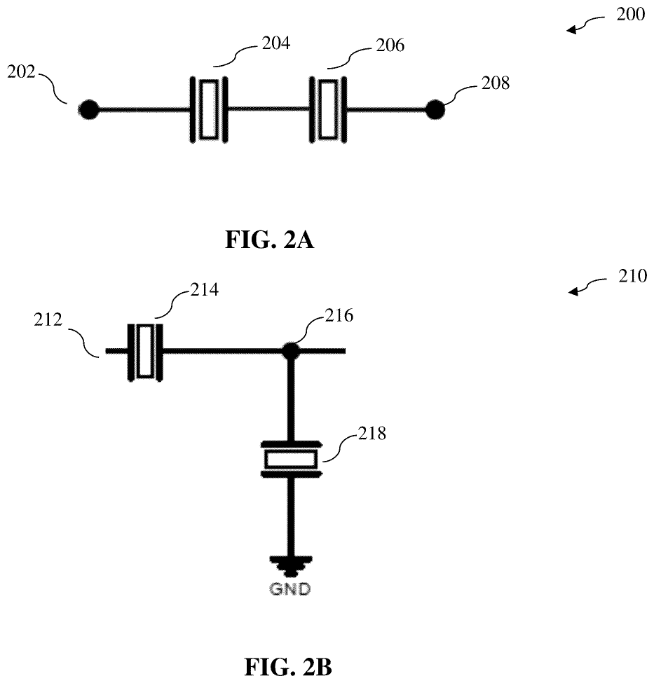

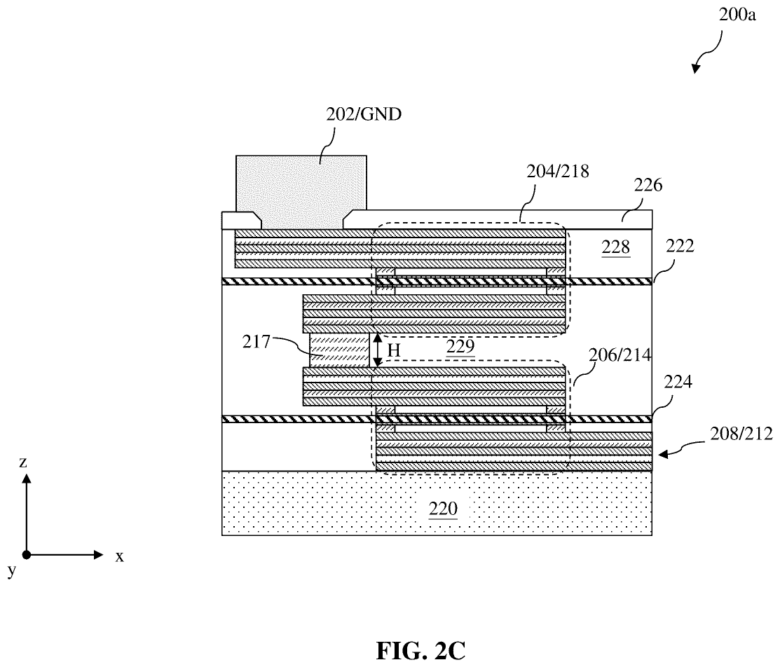

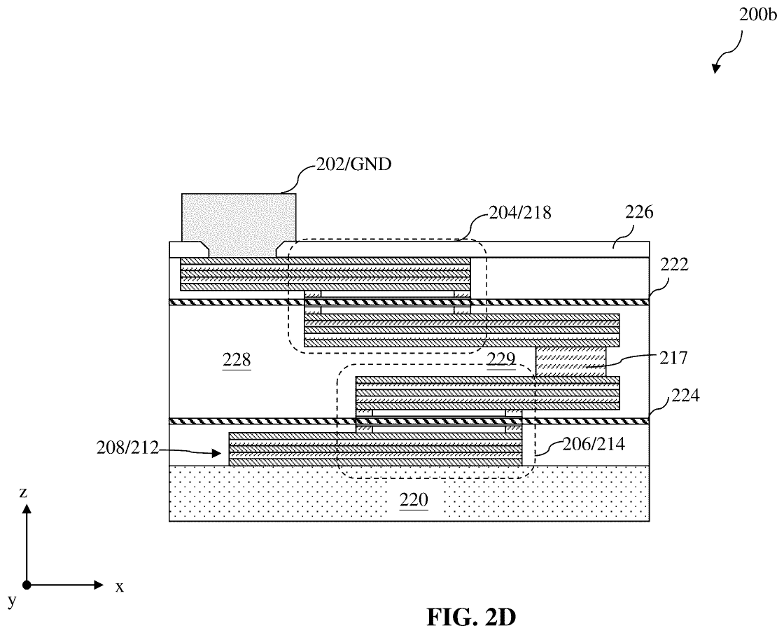

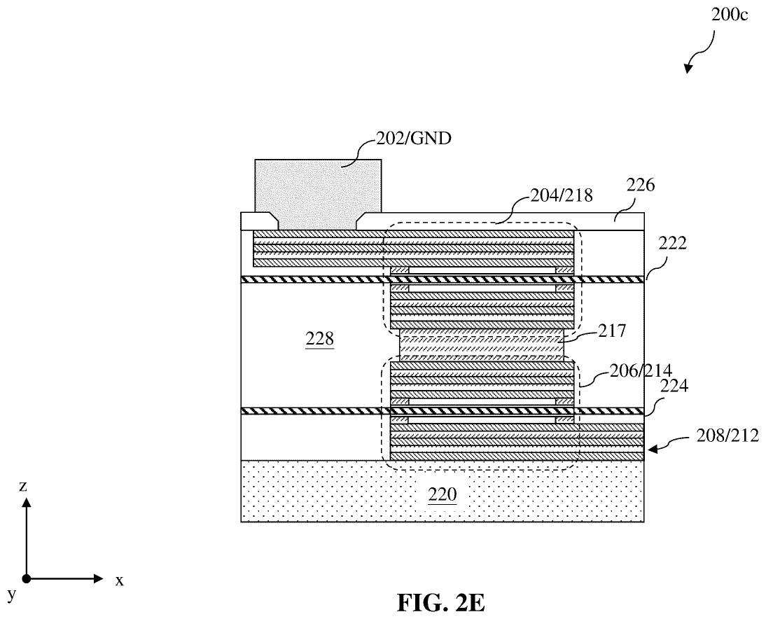

FIGS. 2A, 2B, 3A, 4A, and 5A each illustrates a filter circuit including BAW structures, according to embodiments of the present disclosure. FIGS. 2C-2E, 3B, 4B, and 5B illustrate cross-sectional views of the respective filter circuit with the BAW resonators vertically stacked in the z-direction. The BAW resonators and connection structures in FIGS. 2A-5B may be similar to BAW resonator 100 and connection structure 101, respectively, and the detailed description of the BAW resonators and the connections structures is not repeated.

FIGS. 2A and 2B illustrate two BAW resonators connected in series. In some embodiments, FIG. 2A illustrates a circuit 200 having two resonators 204 and 206 (e.g., series resonators) cascading between a terminal 202 and a terminal 208, and FIG. 2B illustrates a circuit 210 having a resonator 214 (e.g., a series resonator) and a resonator 218 (e.g., a shunt resonator) connected at a joint point 216 between terminal 212 and ground (GND).

FIG. 2C illustrates a configuration 200a of circuits 200 and 210, according to some embodiments. As shown in FIG. 2C, resonator 206/214 (e.g., representing resonator 206 or resonator 214) may be a bottom resonator disposed on a substrate 220, which may include any suitable material such as silicon, glass, epoxy, carbon, plastic, or any combination thereof. Resonator 206/214 may include a piezoelectric layer 224, similar to piezoelectric layer 102 and may extend in the x-y plane. A first/top electrode of resonator 206/214 may be over piezoelectric layer 224, and a second/bottom electrode of resonator 206/214 may be under piezoelectric layer 224. A first/top reflector structure may be electrically connected to and over the first electrode of resonator 206/214, and a second/bottom reflector structure may be electrically connected to and under the second electrode of resonator 206/214. The second reflector structure of resonator 206/214 may be disposed on, e.g., in contact with, substrate 220. The first reflector structure of resonator 206/214 may be electrically connected to resonator 204/218 (e.g., representing resonator 204 or resonator 218). The second reflector structure (or the second electrode) of resonator 206/214 may be electrically connected to terminal 208 or 212.

Resonator 204/218 may be a top resonator and may include a piezoelectric layer 222, similar to piezoelectric layer 102 and may extend in the x-y plane. A first/top electrode of resonator 204/218 may be over piezoelectric layer 222, and a second/bottom electrode of resonator 204/218 may be under piezoelectric layer 222. A first/top reflector structure may be electrically connected to and over the first electrode of resonator 204/218, and a second/bottom reflector structure may be electrically connected to and under the second electrode of resonator 204/218. The second reflector structure of resonator 204/218 may be electrically connected to resonator 206/214. As shown in FIG. 2C, the second reflector structure (or the second electrode) of resonator 204/218 is electrically connected to first reflector structure (or the first electrode) of resonator 206/214 by a via structure 217. In some embodiments, via structure 217 may correspond to the electrically coupling between resonators 204 and 206 in circuit 200. In some embodiments, via structure 217 may correspond to the joint point 216 between resonators 214 and 218. The first reflector structure (or the first electrode) of resonator 204/218 may be electrically connected to terminal 202 or GND. Via structure 217 may include a suitable conductive material such as one or more of copper (Cu), tungsten (W), aluminum copper (AlCu), molybdenum (Mo), and/or platinum (Pt). In some embodiments, via structure 217 includes copper.

In some embodiments, resonator 204/218 and resonator 206/214 have the same or similar lateral dimensions in the x-y plane, and the vertical projections of which may be at least partially overlapped in the x-y plane. In some embodiments, the vertical projections of resonator 204/218 and resonator 206/214 fully overlap in the x-y plane, effectively reducing the area occupied by the two resonators in the x-y plane. The second reflector structure of resonator 204/218 and the first reflector structure of resonator 206/214 may extend towards terminal 202/GND in the x-y plane such that the vertical projection of via structure 217 has partial, little, or no overlap with the vertical projections of resonator 204/218 and resonator 206/214. In some embodiments, via structure 217 is located on the side of resonator 204/218 that is closer to terminal 202/GND.

Circuit 200 may also include an insulating structure 228, over substrate 220, surrounding resonator 204/218, resonator 206/214, and via structure 217. Insulating structure 228 may provide insulation between conductive structures in circuit 200, and may include a suitable insulating structure such as one or more of silicon oxide, silicon nitride, silicon oxynitride, resin, glass, air gap, etc. In some embodiments, insulating structure 228 includes silicon oxide. In some embodiments, the top surface of insulating structure 228 is coplanar with the first reflector structure of resonator 204/218. Circuit 200 may also include a cover layer 226 over insulating structure 228 and the first electrode of resonator 204/218. Cover layer 226 may have similar materials as insulating structure 228. In some embodiments, cover layer 226 includes silicon oxide. Cover layer 226 may insulate resonator 204/218 and have an opening such that terminal 202/GND is electrically connected to the first reflector structure of resonator 204/218.

Insulating structure 228 may include an insulating layer 229 positioned between the second reflector structure of resonator 204/218 and the first reflector structure of resonator 206/214. In some embodiments, insulating layer 229 includes silicon oxide. The thickness of insulating layer 229 may be the same as that of via structure 217, and may be between about 3 μm and about 5 μm. In some embodiments, the first reflector structure of resonator 206/214 is at the same polarity of the second reflector structure of resonator 204/218, the thickness of insulating layer 229 may reduce or avoid parasitic capacitance between the two resonators.

FIG. 2D illustrates another configuration 200b of circuits 200 and 210, according to some embodiments. Different from configuration 200a, resonator 204/218 and resonator 206/214 may partially overlap in the x-y plane. Also, the second electrode of resonator 204/218 and the first electrode of resonator 206/214 may extend away from terminal 202/GND in the x-y plane such that via structure 217 is located on the side of resonator 204/218 that is further away from terminal 202/GND.

FIG. 2E illustrates another configuration 200c of circuits 200 and 210, according to some embodiments. Resonator 204/218 and resonator 206/214 may fully overlap in the x-y plane. Different from configurations 200a and 200b, the second electrode of resonator 204/218 and the first electrode of resonator 206/214 may not extend in the x-y plane such that via structure 217 is located between resonator 204/218 and resonator 206/214. In some embodiments, the vertical projection of via structure 217 is fully overlapped with the vertical projections of resonator 204/218 and resonator 206/214.

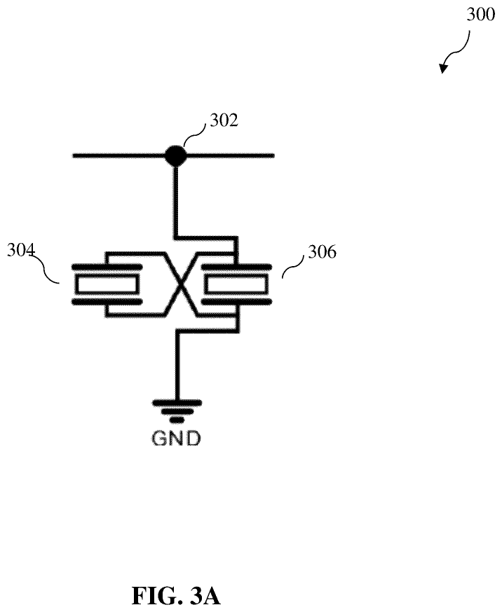

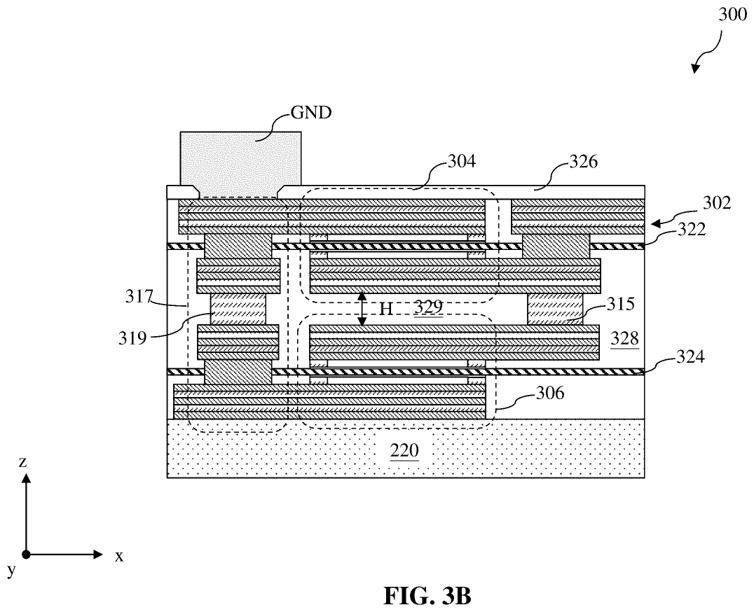

FIG. 3A illustrates a circuit 300 having two resonators 304 and 306 connected in antiparallel between a terminal 302 and ground (GND). A first electrode of resonator 304 is electrically connected to a second electrode of resonator 306, and a second electrode of resonator 304 is electrically connected to a first electrode of resonator 306. In some embodiments, resonators 304 and 306 are similar to or the same as BAW resonator 100.

FIG. 3B illustrates a configuration of circuit 300, according to some embodiments. As shown in FIG. 3B, resonator 306 (e.g., a bottom resonator) may be disposed on a substrate 220. Resonator 306 may include a piezoelectric layer 324, similar to piezoelectric layer 102 and may extend in the x-y plane. A first/top electrode of resonator 306 may be over piezoelectric layer 324, and a second/bottom electrode of resonator 306 may be under piezoelectric layer 324. A first/top reflector structure may be electrically connected to and over the first electrode of resonator 306, and a second/bottom reflector structure may be electrically connected to and under the second electrode of resonator 306. The second reflector structure of resonator 306 may be disposed on, e.g., in contact with, substrate 220. The first reflector structure of resonator 306 may be electrically connected to resonator 304.

Resonator 304 (e.g., a top resonator) may include a piezoelectric layer 322, similar to piezoelectric layer 102 and may extend in the x-y plane. A first/top electrode of resonator 304 may be over piezoelectric layer 322, and a second/bottom electrode of resonator 304 may be under piezoelectric layer 322. A first/top reflector structure may be electrically connected to and over the first electrode of resonator 304, and a second/bottom reflector structure may be electrically connected to and under the second electrode of resonator 304.

As shown in FIG. 3B, the second reflector structure (or the second electrode) of resonator 304 is electrically connected to first reflector structure (or the first electrode) of resonator 306 by a via structure 315, and the second reflector structure (or the second electrode) of resonator 306 is electrically connected to first reflector structure (or the first electrode) of resonator 304 by a connection structure 317. The first reflector structure (or the first electrode) of resonator 304 may be electrically connected to GND, and the second reflector structure (or the second electrode) of resonator 304 may be electrically connected to terminal 302 through another via structure. The second reflector structure of resonator 306 may extend towards GND, and may be electrically connected to GND by connection structure 317. Via structure 315 may include a suitable conductive material such as one or more of copper (Cu), tungsten (W), aluminum copper (AlCu), molybdenum (Mo), and/or platinum (Pt). In some embodiments, via structure 315 includes copper. In some embodiments, connection structure 317 is similar to connection structure 101 except that the stack structures at the ends (e.g., similar to 103 and 105) are part of the first and second electrodes of resonators 304 and 306. For example, connection structure 317 includes via structure 319 (e.g., similar to via structure 109) between the stack structures that respectively level with the second reflector structure of resonator 304 and the first reflector structure of resonator 306.

In some embodiments, resonator 304 and resonator 306 have the same or similar lateral dimensions in the x-y plane, and the vertical projections of which may be at least partially overlapped in the x-y plane. In some embodiments, the vertical projections of resonator 304 and resonator 306 fully overlap in the x-y plane, effectively reducing the area occupied by the two resonators in the x-y plane. The second reflector structure of resonator 304 and the first reflector structure of resonator 306 may extend away from GND in the x-y plane such that the vertical projection of via structure 315 has little or no overlap with the vertical projections of resonators 304 and 306. In some embodiments, via structure 315 is located on the side of resonator 304 that is further away from GND.

Circuit 300 may also include an insulating structure 328, over substrate 220, surrounding resonators 304 and 306, and via structure 315 and connection structure 317. Insulating structure 328 may be similar to insulating structure 228, and may include silicon oxide. In some embodiments, the top surface of insulating structure 328 is coplanar with the first reflector structure of resonator 304. Circuit 300 may also include a cover layer 326 similar to cover layer 226. Cover layer 326 may insulate resonator 304 and have an opening such that GND is electrically connected to the first reflector structure of resonator 304.

Insulating structure 328 may include an insulating layer 329 positioned between the second reflector structure of resonator 304 and the first reflector structure of resonator 306. In some embodiments, insulating layer 329 includes silicon oxide. The thickness of insulating layer 329 may be the same as that of via structures 315 and 319, and may be between about 3 μm and about 5 μm. In some embodiments, the first reflector structure of resonator 306 is at the same polarity of the second reflector structure of resonator 304, the thickness of insulating layer 329 may reduce or avoid parasitic capacitance between the two resonators.

In some embodiments, connection structure 317 may extend through at least one piezoelectric layer, e.g., 322 and/or 324, in the z-direction. As shown in FIG. 3B, connection structure 317 may be in contact with piezoelectric layer 322 and/or 324 at respective via structures (e.g., 105 and/or 113) between stack structures.

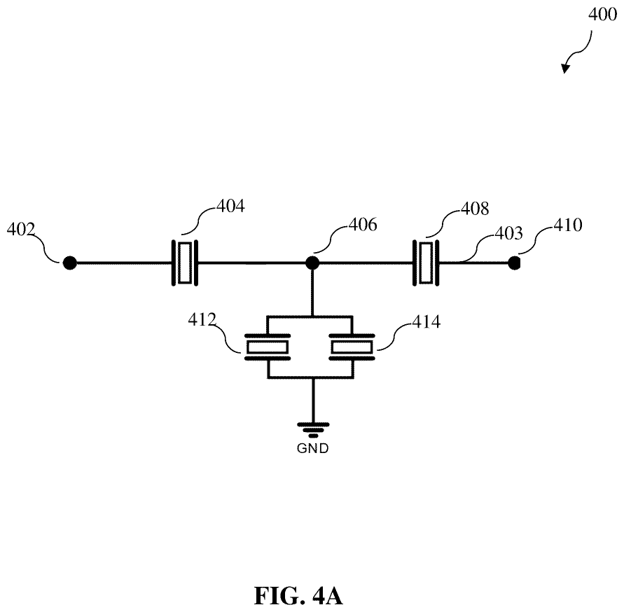

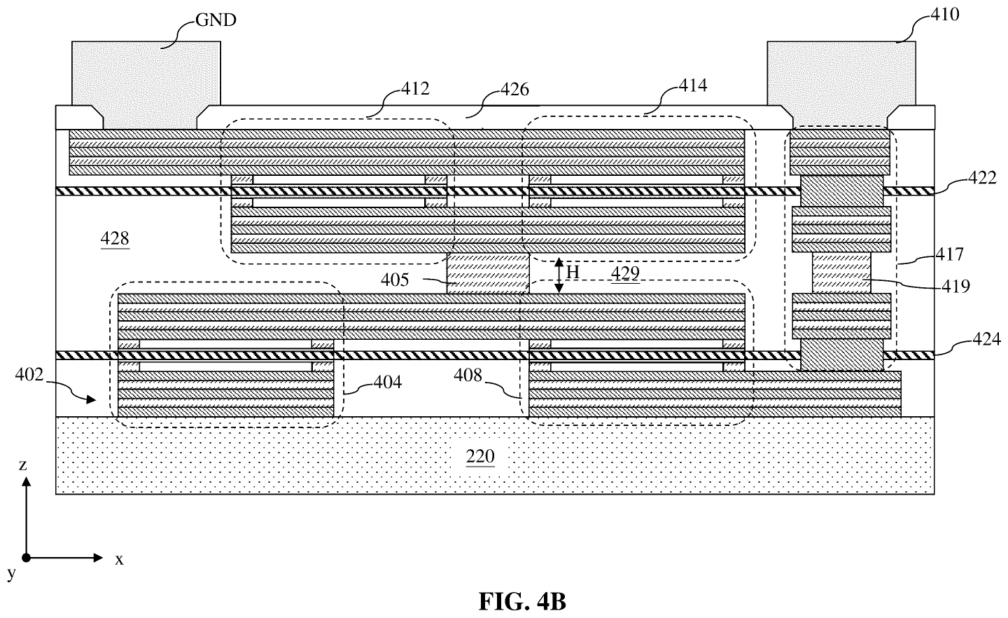

FIG. 4A illustrates a circuit 400 having four resonators 404, 408, 412, and 414. Resonators 404 and 408 (e.g., series resonators) are connected in series between a terminal 402 and a terminal 410. Resonators 412 and 414 (e.g., shunt resonators) are connected in parallel between a joint point 406 (between resonators 404 and 408) and GND. First electrodes of resonators 404 and 408 are electrically connected, a second electrode of resonator 404 is electrically connected to terminal 402, and a second electrode of resonator 408 is electrically connected to terminal 410. First electrodes of resonators 412 and 414 are electrically connected and further to GND, and second electrodes of resonators 412 and 414 are electrically connected and further to the first electrodes of resonators 404 and 408 (e.g., at joint point 406). In some embodiments, resonators 404, 408, 412, and 414 are similar to or the same as BAW resonator 100.

FIG. 4B illustrates a configuration of circuit 400, according to some embodiments. As shown in FIG. 4B, resonators 404 and 408 (e.g., bottom resonators) may be disposed on a substrate 220. Resonators 404 and 408 may share a same piezoelectric layer 424, similar to piezoelectric layer 102 and may extend in the x-y plane. In some embodiments, piezoelectric layer 424 extend in the x-y direction in both resonators 404 and 408. First/top electrodes of resonators 404 and 408 may be over piezoelectric layer 424, and second/bottom electrodes of resonators 404 and 408 may be under piezoelectric layer 424. Respective first/top reflector structures may be electrically connected to and over the first electrodes of resonators 404 and 408, and respective second/bottom reflector structures may be electrically connected to and under the second electrodes of resonators 404 and 408. The second reflector structures of resonators 404 and 408 may be disposed on, e.g., in contact with, substrate 220. The first reflector structures of resonators 404 and 408 may be electrically connected. In some embodiments, the first reflector structures of resonators 404 and 408 may be in contact and level with each other. For example, the first reflector structures of resonators 404 and 408 may have the same materials. In some embodiments, resonators 404 and 408 are connected by their respective first reflector structures, with their second reflector structures (or second electrodes) separated from each other.

Resonators 412 and 414 (e.g., top resonators) may share a same piezoelectric layer 422, similar to piezoelectric layer 102 and may extend in the x-y plane. In various embodiments, piezoelectric layers 422 and 424 may have the same material or have different materials. First/top electrodes of resonators 412 and 414 may be over piezoelectric layer 422, and second/bottom electrodes of resonators 412 and 414 may be under piezoelectric layer 422. Respective first/top reflector structures may be electrically connected to and over the first electrodes of resonators 412 and 414, and respective second/bottom reflector structures may be electrically connected to and under the second electrodes of resonators 412 and 414. In some embodiments, the first reflector structures of resonators 412 and 414 may be in contact and level with each other. In some embodiments, the second reflector structures of resonators 412 and 414 may be in contact and level with each other. For example, the first reflector structures of resonators 412 and 414 may have the same materials, and the second reflector structures of resonators 412 and 414 may have the same materials. In some embodiments, resonators 412 and 414 are connected to each other by their first reflector structures and second reflector structures.

As shown in FIG. 4B, the connected second reflector structures (or the second electrodes) of resonators 412 and 414 are electrically connected to the connected first reflector structures (or the first electrodes) of resonators 404 and 408 by a via structure 405. The first reflector structure (or the first electrode) of resonator 412 extends towards and is electrically connected to GND. The second reflector structure of resonator 408 may extend towards terminal 410, and may be electrically connected to terminal 410 by a connection structure 417. Via structure 405 may be in contact with the connected second reflector structures of resonators 412 and 414 and the connected first reflector structures of resonators 404 and 408. In some embodiments, the vertical projection of via structure 405 is fully overlapped with the vertical projection of connected resonators 412 and 414, or the vertical projection of connected resonators 404 and 408. Via structure 405 may include a suitable conductive material such as one or more of copper (Cu), tungsten (W), aluminum copper (AlCu), molybdenum (Mo), and/or platinum (Pt). In some embodiments, via structure 405 includes copper. In some embodiments, connection structure 417 is similar to connection structure 101. For example, connection structure 417 includes a via structure 419 (e.g., similar to via structure 109) between the stack structures that respectively level with the second reflector structure of resonator 414 and the first reflector structure of resonator 408.

In some embodiments, connected resonators 404 and 408 may be at least partially overlapped with connected resonators 412 and 414 in the x-y plane. The second reflector structure of resonator 408 may extend away towards terminal 410 in the x-y plane such that the vertical projection of connection structure 417 has little or no overlap with the vertical projections of the connected resonators.

Circuit 400 may also include an insulating structure 428, over substrate 220, surrounding resonators 404, 408, 412, and 414, and connection structure 417. Insulating structure 428 may be similar to insulating structure 228, and may include silicon oxide. In some embodiments, the top surface of insulating structure 428 is coplanar with the first reflector structures of resonators 412 and 414. Circuit 400 may also include a cover layer 426 similar to cover layer 226. Cover layer 426 may insulate resonators 412 and 414 and have an opening such that GND and terminal 410 are electrically connected to the respective reflector structures.

Insulating structure 428 may include an insulating layer 429 positioned between the second reflector structures of resonators 412 and 414 and the first reflector structures of resonators 404 and 408. In some embodiments, insulating layer 429 includes silicon oxide. The thickness of insulating layer 429 may be the same as that of via structure 419, and may be between about 3 μm and about 5 μm. In some embodiments, the first reflector structures of resonators 404 and 408 are at the same polarity of the second reflector structures of resonators 412 and 414, the thickness of insulating layer 329 may reduce or avoid parasitic capacitance between the two resonators.

In some embodiments, connection structure 417 may extend through at least one piezoelectric layer, e.g., 422 and/or 424, in the z-direction. As shown in FIG. 4B, connection structure 417 may be in contact with piezoelectric layer 422 and/or 424 at respective via structures (e.g., 105 and/or 113) between stack structures.

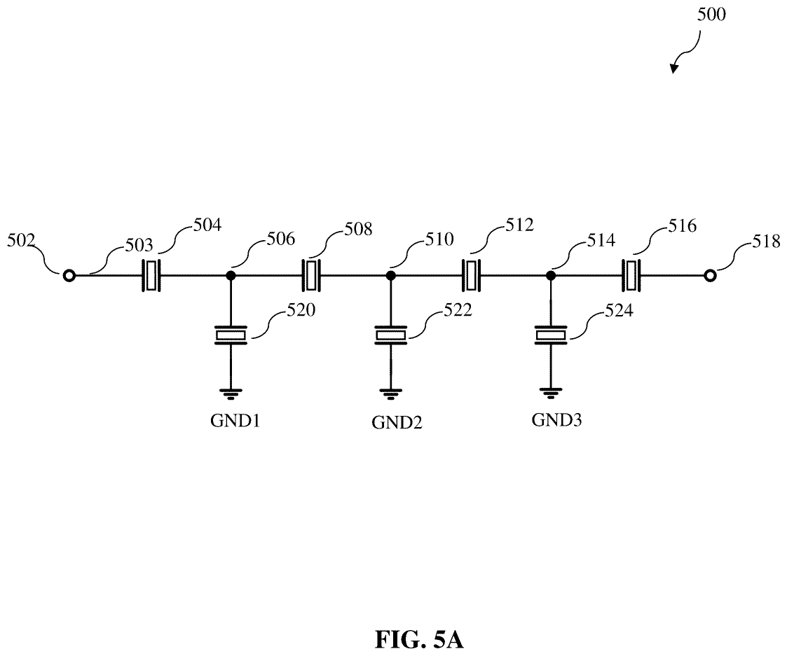

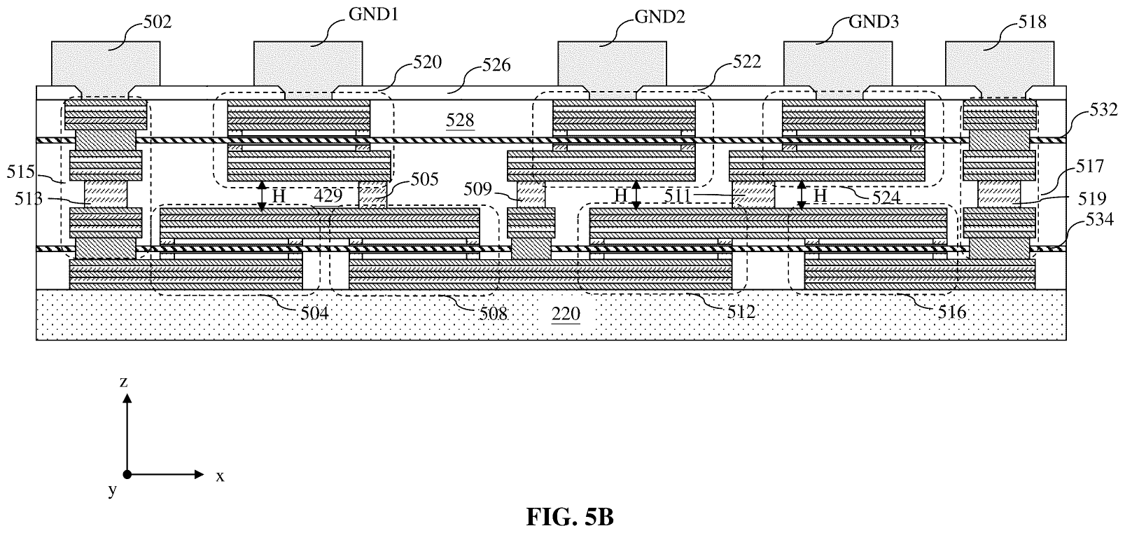

FIG. 5A illustrates a circuit 500 having seven resonators 504, 508, 512, 516, 520, 522, and 524. Resonators 504, 508, 512, and 516 (e.g., series resonators) are connected in series between a terminal 502 and a terminal 518. Resonators 520, 522, and 524 (e.g., shunt resonators) are each connected between a respective joint point 5065, 510, or 514 (between two series resonators) and GND. For illustrative purposes, resonators 520, 522, and 524 are respectively connected to GND1, GND2, and GND3. First electrodes of resonators 504 and 508 are electrically connected, and first electrodes of resonators 512 and 516 are electrically connected. A second electrode of resonator 504 is electrically connected to terminal 502, and a second electrode of resonator 516 is electrically connected to terminal 518. First electrodes of resonators 520, 522, and 524 are respectively connected to GND1, GND2, and GND3. A second electrode of resonator 520 is electrically connected to a joint point between resonators 504 and 508, a second electrode of resonator 522 is electrically connected to a joint point between resonators 508 and 512, and a second electrode of resonator 524 is electrically connected to a joint point between resonators 512 and 516. In some embodiments, resonators 504, 508, 512, 516, 520, 522, and 524 are similar to or the same as BAW resonator 100.

FIG. 5B illustrates a configuration of circuit 400, according to some embodiments. As shown in FIG. 5B, resonators 504, 508, 512, and 516 (e.g., bottom resonators) may be disposed on a substrate 220. Resonators 504, 508, 512, and 516 may share a same piezoelectric layer 534, similar to piezoelectric layer 102 and may extend in the x-y plane. In some embodiments, piezoelectric layer 534 extend in the x-y direction in resonators 504, 508, 512, and 516. First/top electrodes of resonators 504, 508, 512, and 516 may be over piezoelectric layer 534, and second/bottom electrodes of resonators 504, 508, 512, and 516 may be under piezoelectric layer 534. Respective first/top reflector structures may be electrically connected to and over the first electrodes of resonators 504, 508, 512, and 516, and respective second/bottom reflector structures may be electrically connected to and under the second electrodes of resonators 504, 508, 512, and 516. The second reflector structures of resonators 504, 508, 512, and 516 may each be disposed on, e.g., in contact with, substrate 220.

The first reflector structures of resonators 504 and 508 may be electrically connected, and the first reflector structures of resonators 512 and 516 may be electrically connected. In some embodiments, the first reflector structures of resonators 504 and 508 may be in contact and level with each other with their second reflector structures separated from each other, and the first reflector structures of resonators 512 and 516 may be in contact and level with each other with their second reflector structures separated from each other. For example, the first reflector structures of resonators 504 and 508 may have the same materials, and the first reflector structures of resonators 512 and 516 may have the same materials. In some embodiments, the first reflector structures of resonators 504, 508, 512, and 516 may have the same materials. In some embodiments, resonators 504 and 508 are connected by their respective first reflector structures, and resonators 512 and 516 are connected by their respective first reflector structures.

The second reflector structures of resonators 508 and 512 may be electrically connected with their first reflector structures separated from each other. In some embodiments, the second reflector structures of resonators 508 and 512 may be in contact and level with each other. For example, the second reflector structures of resonators 508 and 512 may have the same materials. In some embodiments, resonators 508 and 512 are connected by their respective second reflector structures. The second reflector structure of resonator 504 may extend in the x-y plane and be electrically connected to terminal 502 by a connection structure 515. The second reflector structure of resonator 516 may extend in the x-y plane and be electrically connected to terminal 518 by a connection structure 517.

Resonators 520, 522, and 524 (e.g., top resonators) may share a same piezoelectric layer 532, similar to piezoelectric layer 102 and may extend in the x-y plane. In various embodiments, piezoelectric layers 532 and 534 may have the same material or have different materials. First/top electrodes of resonators 520, 522, and 524 may be over piezoelectric layer 532, and second/bottom electrodes of resonators 520, 522, and 524 may be under piezoelectric layer 532. Respective first/top reflector structures may be electrically connected to and over the first electrodes of resonators 520, 522, and 524, and respective second/bottom reflector structures may be electrically connected to and under the second electrodes of resonators 520, 522, and 524. The first/top reflector structure of resonator 520 may be electrically connected to GND1, the first/top reflector structure of resonator 522 may be electrically connected to GND2, and the first/top reflector structure of resonator 524 may be electrically connected to GND3.

As shown in FIG. 5B, the second/bottom reflector structure (or the second electrode) of resonator 520 is electrically connected to the connected first reflector structures (or the first electrodes) of resonators 504 and 508 by a via structure 505. The second/bottom reflector structure (or the second electrode) of resonator 522 is electrically connected to the connected second reflector structures (or the second electrodes) of resonators 508 and 512. The second/bottom reflector structure (or the second electrode) of resonator 524 is electrically connected to the connected first reflector structures (or the first electrodes) of resonators 512 and 516. In some embodiments, the second reflector structures of each of resonators 520, 522, and 524 may extend in the x-y direction towards the respective via structure to form electrical connection.

Via structures 505, 509, and 511 may each be in contact with the respective connected second reflector structure or connected first reflector structures. Via structures 505, 509, and 511 may each include a suitable conductive material such as one or more of copper (Cu), tungsten (W), aluminum copper (AlCu), molybdenum (Mo), and/or platinum (Pt). In some embodiments, via structures 505, 509, and 511 each includes copper. In some embodiments, connection structure 517 is similar to connection structure 101. For example, connection structure 517 includes a via structure 519 (e.g., similar to via structure 109) between the stack structures that respectively level with the second reflector structure of resonator 524 and the first reflector structure of resonator 516.

In some embodiments, resonators 520 may be at least partially overlapped with connected resonators 504 and 508 in the x-y plane, and resonators 522 and 524 may each be at least partially overlapped with connected resonators 512 and 516 in the x-y plane. The second reflector structure of resonator 508 may extend towards terminal 502 in the x-y plane such that the vertical projection of connection structure 515 has little or no overlap with the vertical projections of the connected resonators 504 and 508, and the second reflector structure of resonator 516 may extend towards terminal 518 in the x-y plane such that the vertical projection of connection structure 517 has little or no overlap with the vertical projections of the connected resonators 512 and 516.

Circuit 500 may also include an insulating structure 528, over substrate 220, surrounding resonators 504, 508, 512, 516, 520, 522, and 524, and connection structures 515 and 517. Insulating structure 528 may be similar to insulating structure 228, and may include silicon oxide. In some embodiments, the top surface of insulating structure 528 is coplanar with the first reflector structures of resonators 520, 522, and 524. Circuit 500 may also include a cover layer 526 similar to cover layer 226. Cover layer 526 may insulate resonators 520, 522, and 524 and have openings such that GND1, GND2, GND3, and terminals 502 and 518 are electrically connected to the respective reflector structures.

Insulating structure 528 may include an insulating layer 529 positioned between the second reflector structure of resonator 520 and the first reflector structures of resonators 504 and 508, the second reflector structure of resonator 522 and the first reflector structure of resonator 512, and the second reflector structure of resonator 524 and the first reflector structures of resonators 512 and 516. In some embodiments, insulating layer 529 includes silicon oxide. The thickness of insulating layer 529 may be the same as that of via structures 513, 519, 505, 509, and 511, and may be between about 3 μm and about 5 μm. In some embodiments, the first reflector structures of resonators 504, 508, 512, and 516 are at the same polarity of the second reflector structures of resonators 520, 522, and 524, the thickness of insulating layer 529 may reduce or avoid parasitic capacitance between the two resonators facing each other.

In some embodiments, connection structures 515 and 517 may each extend through at least one piezoelectric layer, e.g., 532 and/or 534, in the z-direction. As shown in FIG. 5B, connection structure 513 and 517 may be in contact with piezoelectric layers 532 and/or 534 at respective via structures (e.g., 105 and/or 113) between stack structures.

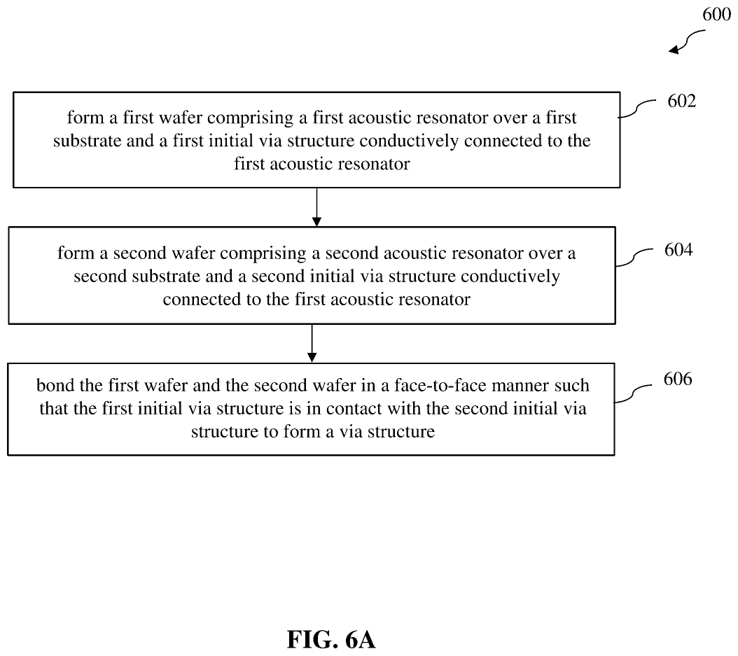

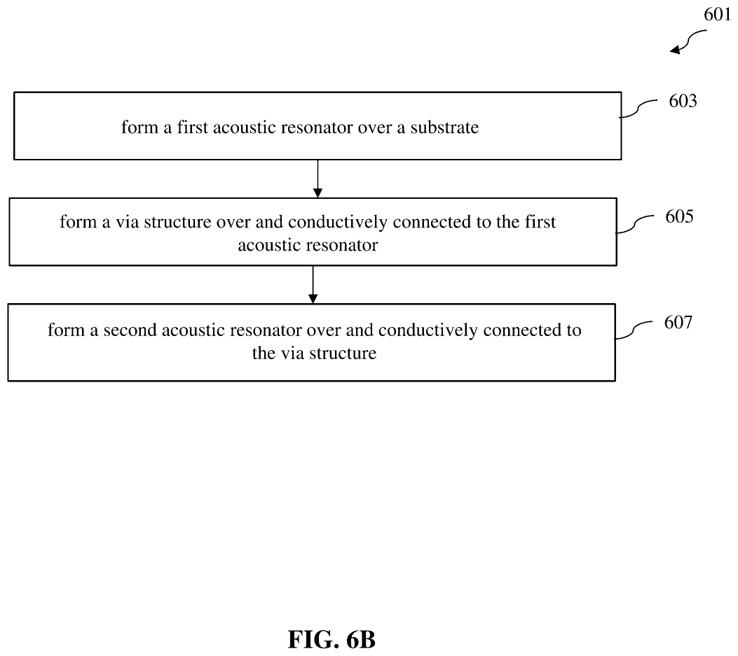

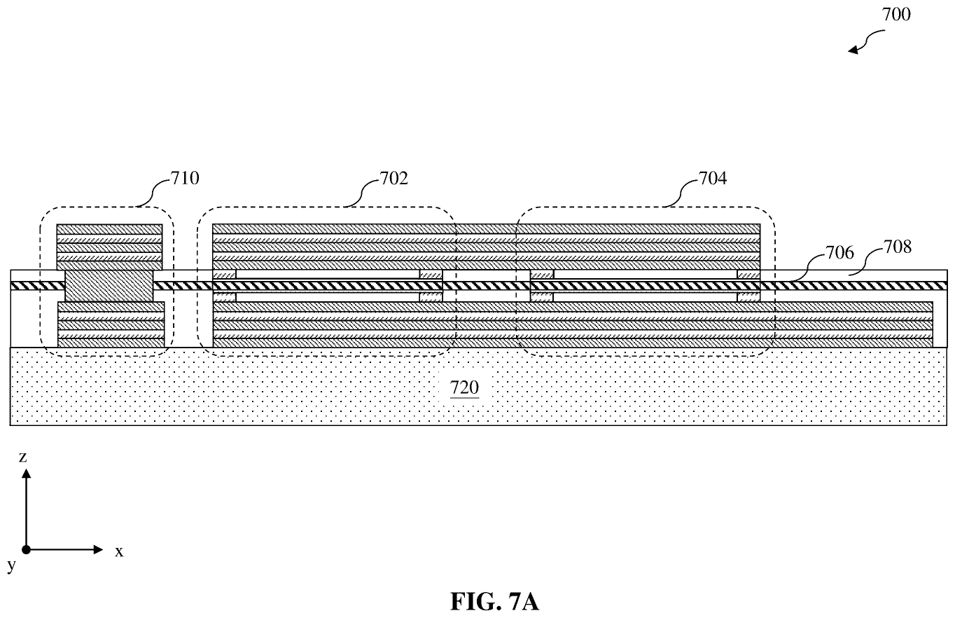

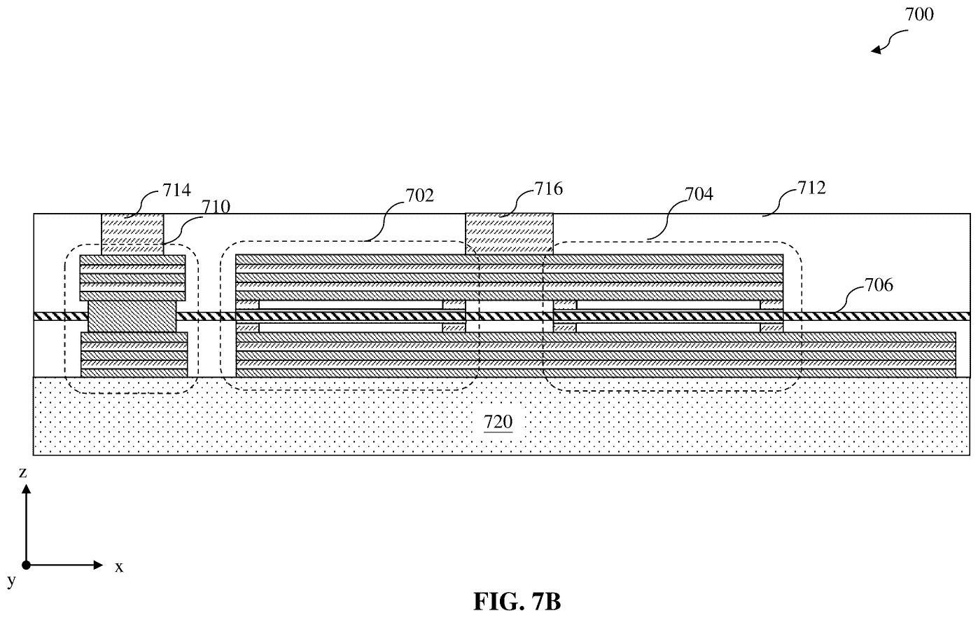

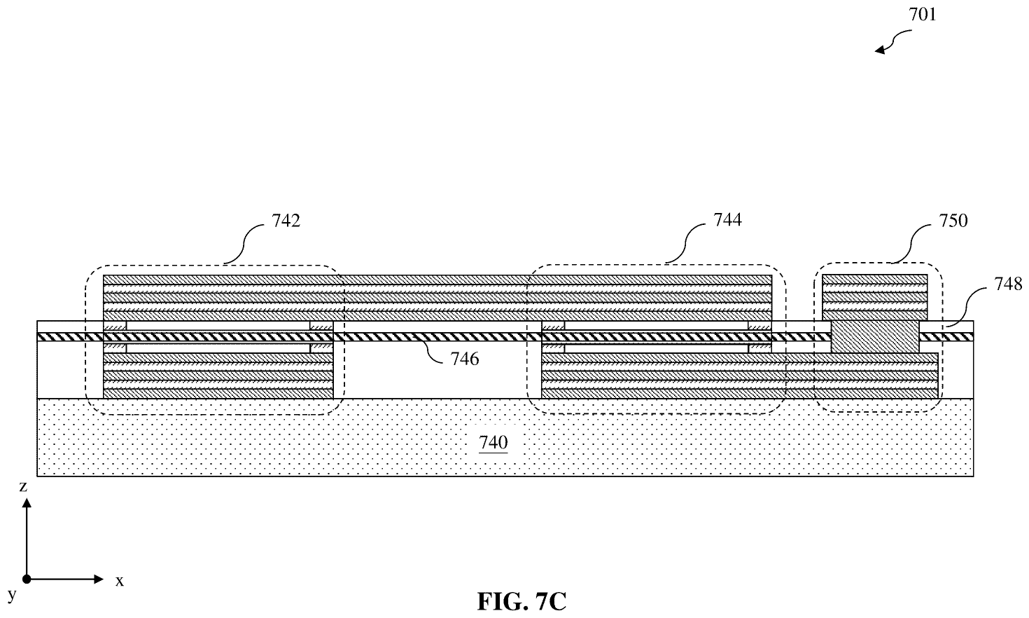

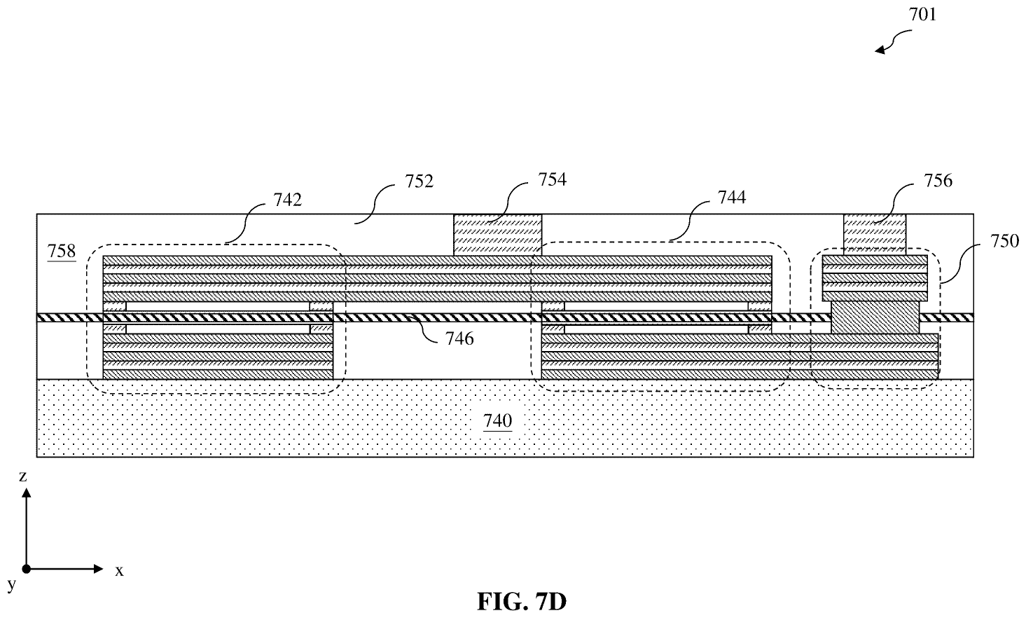

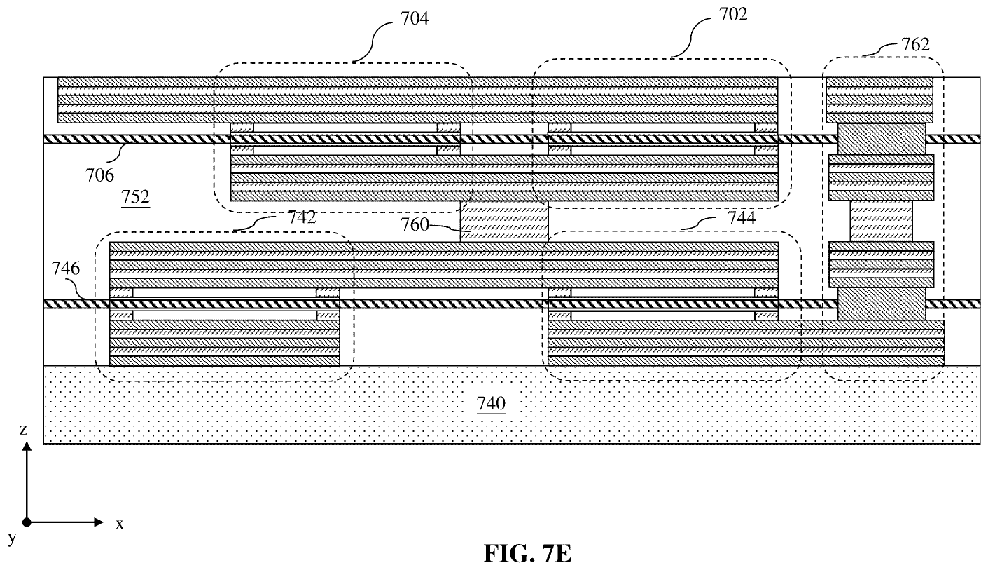

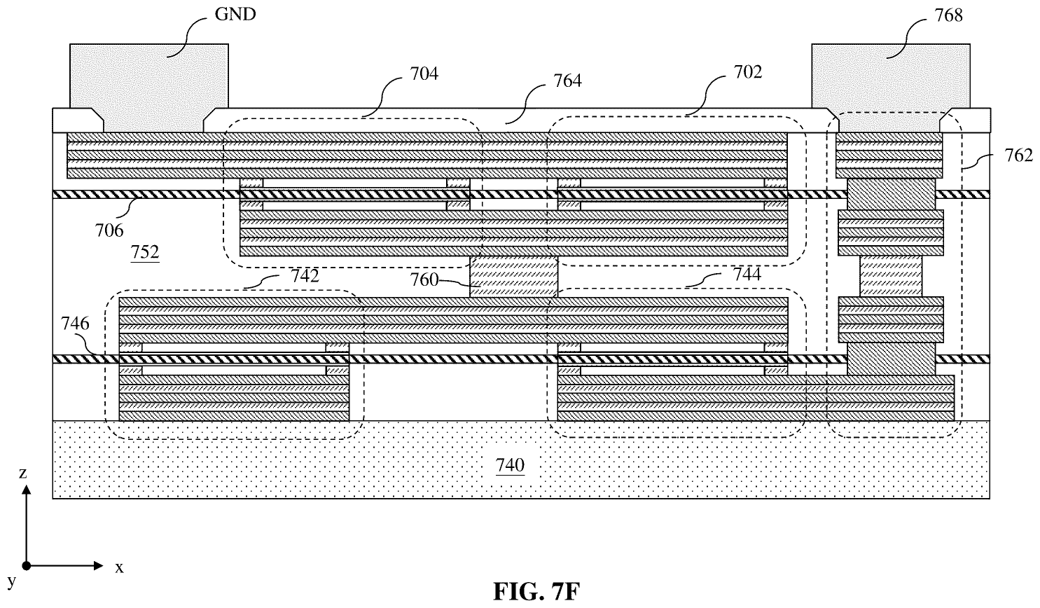

FIG. 6A is a flowchart of a method 600 for forming a BAW filter structure, according to some embodiments of the present disclosure. Method 600 is merely an example, and is not intended to limit the present disclosure beyond what is explicitly recited in the claims. Additional operations can be provided before, during, and after the method 600, and some operations described can be replaced, eliminated, or moved around for additional embodiments of method 600. Method 600 will be described in more detail below. FIGS. 7A-7F illustrate structures of the BAW filter structure at different stages of alternative fabrication processes. In some embodiments, the BAW structure may be an example of circuit 400. In some embodiments, the BAW filter structure is formed by bonding of two wafers.

At step 602, a first wafer having a first acoustic resonator over a first substrate and a first initial via structure conductively connected to the first acoustic resonator, is formed. FIGS. 7A and 7B illustrate corresponding structures.

As shown in FIG. 7A, a first wafer 700 is formed. First wafer 700 may include a first substrate 720, one or more first acoustic resonators 702 (and 704) over first substrate 720. In some embodiments, first substrate 720 includes silicon. To form first wafer 700, one or more layers of materials may be deposited on first substrate 720. For example, a plurality of conductive materials of alternating acoustic impedances (e.g., aluminum copper and tungsten or W/AlCu) may be deposited and patterned on first substrate 720 to form a reflector structure (e.g., a bottom reflector structure). An insulating layer, conductive portions, and an electrode may be deposited and patterned on the reflector structure. A piezoelectric layer 706 may be deposited on the electrode. In some embodiments, the same piezoelectric layer 706 is deposited for more than one acoustic resonators (e.g., for acoustic resonators 702 and 704), as shown in FIG. 7A. Another electrode, another insulating layer, other conductive portions, and a plurality of alternating metal layers of high/low acoustic impedances (e.g., to form a top reflector structure) may be deposited and patterned over piezoelectric layer 706. A dielectric layer 708 may also be deposited and patterned to insulate the conductive parts of first wafer 700. In some embodiments, piezoelectric layer 706 includes AlN, electrodes include tungsten and/or aluminum copper, the insulating layers include silicon oxide, and conductive portions may include aluminum copper. Dielectric layer 708 includes silicon oxide.

In some embodiments, an initial connection structure 710 is formed on first substrate 720. Initial connection structure 710 may include one or more stack structures including a plurality of alternating metal layers of high/low acoustic impedances, e.g., W/AlCu stack. In some embodiments, the stack structures of initial connection structure 710 are formed in the same processes/steps that form the reflector structures of first acoustic resonator 702 (or 704). Initial connection structure 710 may also include a via structure (e.g., tungsten) connecting the stack structures, and another initial via structure 714 over the stack structures. In some embodiments, initial connection structure 710 is surrounded by dielectric layer 708 and extends through piezoelectric layer 706. In some embodiments, the via structure between the stack structures of initial connection structure 710 is in contact with piezoelectric layer 706.

In some embodiments, first acoustic resonators 702 and 704 are formed with respective reflector structures in contact with each other. The top reflector structures of first acoustic resonators 702 and 704 may be deposited in the same process and may not be divided, and the bottom reflector structures of first acoustic resonators 702 and 704 may be deposited in the same process and may not be divided.

As shown in FIG. 7B, a first initial via structure 716 is formed conductively connected to the first acoustic resonator 702 (or 704). A dielectric layer 712 may be formed surrounding first initial via structure 716. The surface of dielectric layer 712 may be planarized to expose first initial via structure 716. In some embodiments, another first initial via structure 714 is formed in contact with initial connection structure 710, e.g., a stack structure of initial connection structure 710. In some embodiments, the surface of dielectric layer 712 may be planarized to expose other first initial via structure 714. In some embodiments, first initial via structure 716 and other initial via structure 714 are formed in the same process, e.g., patterning of dielectric layer 712, deposition, planarization, etc. In some embodiments, first initial via structure 716 and other initial via structure 714 include copper.

The materials may be deposited using one or more suitable deposition processes such as atomic layer deposition, chemical vapor deposition, physical vapor deposition, electroplating, electroless plating, or a combination thereof. The fabrication process may include photolithography, etching (e.g., dry etch and/or wet etch), planarizing (chemical mechanical polishing or CMP), and so on.

At step 604, a second wafer having a second acoustic resonator over a second substrate and a second initial via structure conductively connected to the first acoustic resonator, is formed. FIGS. 7C and 7D illustrate corresponding structures.

As shown in FIG. 7C, a second wafer 701 is formed. Second wafer 701 may include a second substrate 740, one or more second acoustic resonators 742 (and 744) over second substrate 740. Second wafer 701 may include a piezoelectric layer 746 extending in one or more second acoustic resonators 742 and/or 744. A second initial connection structure 750 may also be formed on second substrate 740. In some embodiments, second initial connection structure 750 includes at least one stack structures formed with a plurality of alternating metal layers of high/low acoustic impedances (e.g., W/AlCu). In some embodiments, one of the stack structures is part of the reflector structure of a second acoustic resonator (e.g., 742 or 744), and another stack structure is formed in the same fabrication process that form a reflector structure of a resonator acoustic resonator. A dielectric layer 748 may also be deposited and patterned to insulate the conductive parts of second wafer 701. Details of the materials and fabrication of second wafer 701 may be referred to the description of first wafer 700, and are not repeated.

As shown in FIG. 7D, a second initial via structure 754 is formed conductively connected to the second acoustic resonator 742 (or 744). A dielectric layer 758 may be formed surrounding second initial via structure 754. The surface of dielectric layer 758 may be planarized to expose second initial via structure 754. In some embodiments, another second initial via structure 756 is formed in contact with second initial connection structure 750, e.g., a stack structure of second initial connection structure 750. In some embodiments, the surface of dielectric layer 758 may be planarized to expose other second initial via structure 756. In some embodiments, second initial via structure 754 and other second initial via structure 756 are formed in the same process, e.g., patterning of dielectric layer 758, deposition, planarization, etc. In some embodiments, second initial via structure 754 and other second initial via structure 756 include copper.

At step 606, the first wafer and the second wafer are bonded in a face-to-face manner such that the first initial via structure is in contact with the second initial via structure to form a via structure. FIGS. 7E and 7F illustrate corresponding structures.

As shown in FIG. 7E, first wafer 700 may be flipped and bonded with second wafer 701 in a face-to-face manner to form a bonded structure. First initial via structure 716 may be bonded with, e.g., in contact with, second initial via structure 754 to form a via structure 760. In some embodiments, the bonding includes hybrid bonding, which may include applying heat and/or pressure on the area being bonded. Dielectric layer 712 may be bonded with dielectric layer 758. In some embodiments, other first initial via structure 714 is bonded with other second initial via structure 756 to form a connection structure 762. In some embodiments, the thickness of via structure 760 (or a total thickness of first initial via structure 716 and second initial via structure 754) may be between about 3 μm and about 5 μm. Substrate 720 may be removed from the bonded structure. The removal of first substrate 720 may include a suitable etch and/or planarization.

As shown in FIG. 7F, a cover layer 764 is formed over the bonded structure, covering acoustic resonators 702 and 704. Cover layer 764 may include a plurality of openings that expose part of a reflector structure of first acoustic resonator 704 and/or connection structure 762. Conductive materials may be formed in the openings to provide electrical connection to the acoustic resonators. For example, terminal contacts such as GND and terminal 768 may be formed respectively in contact with a reflector structure of first acoustic resonator 704 and connection structure 762. In some embodiments, cover layer 764 includes silicon oxide, the terminal contacts includes a conductive material such as one or more of tin (Sn), lead (Pb), copper, aluminum, etc. The materials may be deposited using one or more suitable deposition processes such as atomic layer deposition, chemical vapor deposition, physical vapor deposition, electroplating, electroless plating, or a combination thereof. The fabrication process may include photolithography, etching (e.g., dry etch and/or wet etch), planarizing (chemical mechanical polishing or CMP), and so on.

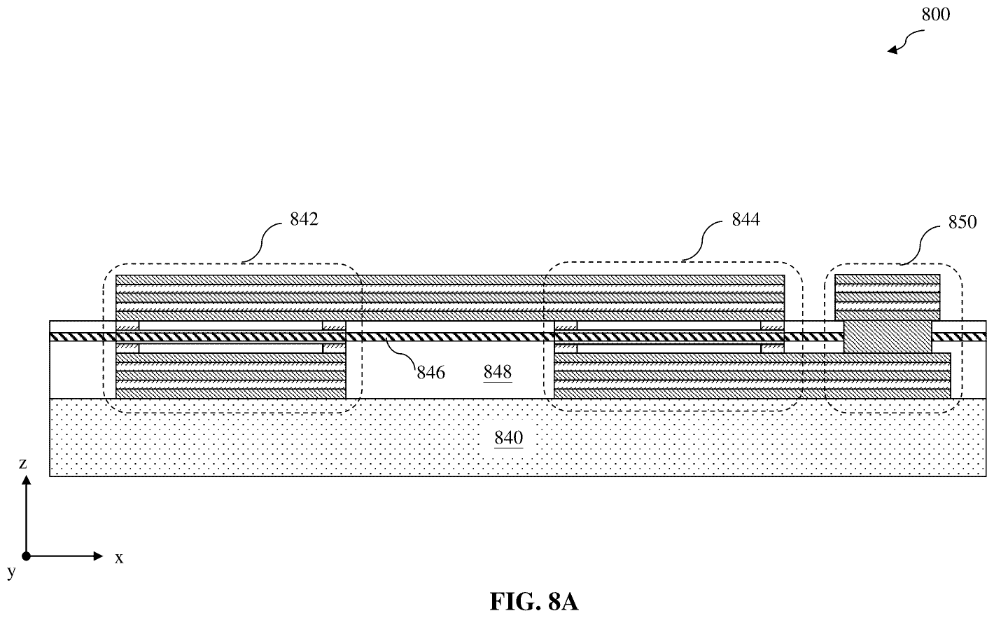

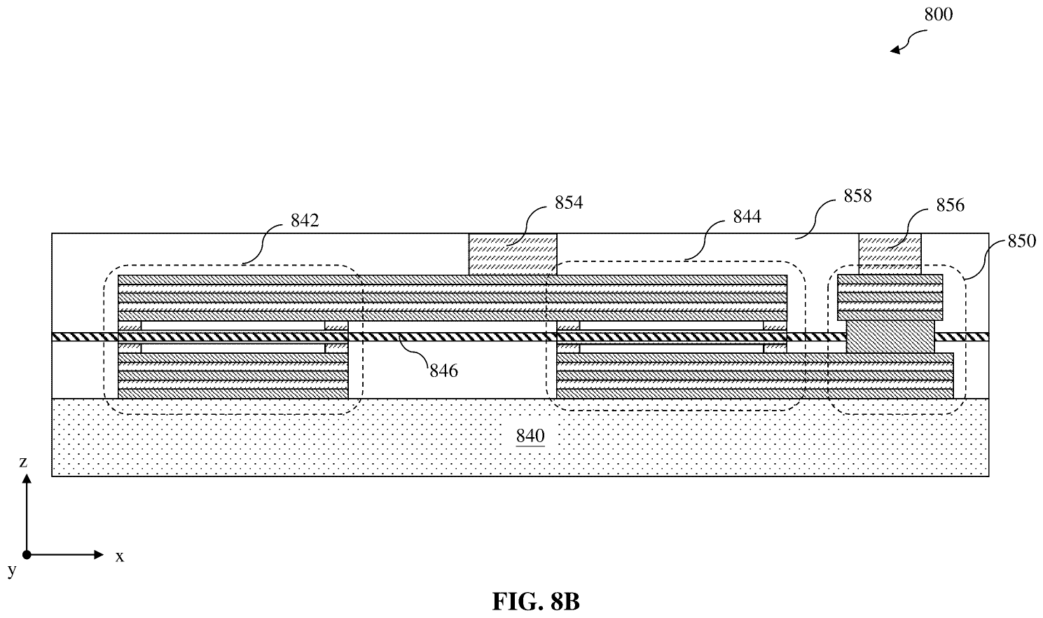

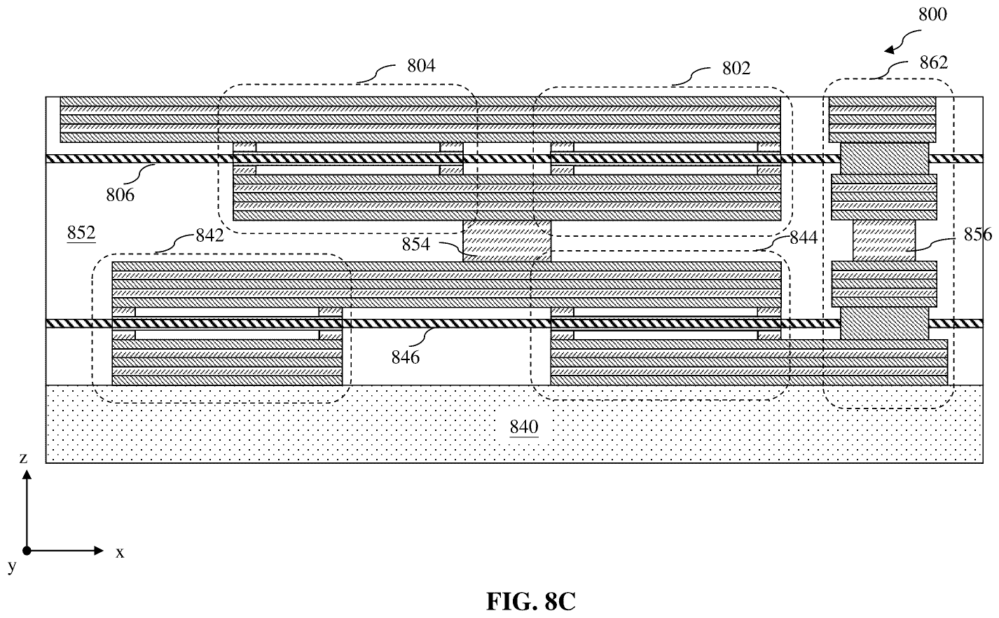

FIG. 6B is a flowchart of another method 601 for forming a BAW filter structure, according to some embodiments of the present disclosure. Method 601 is merely an example, and is not intended to limit the present disclosure beyond what is explicitly recited in the claims. Additional operations can be provided before, during, and after the method 601, and some operations described can be replaced, eliminated, or moved around for additional embodiments of method 601. Method 601 will be described in more detail below. FIGS. 8A-8C illustrate structures of the BAW filter structure at different stages of alternative fabrication processes. In some embodiments, the BAW structure may be an example of circuit 400. In some embodiments, the BAW filter structure is formed on a single/monolithic wafer.

At step 603, an acoustic resonator is formed over a substrate. FIG. 8A illustrates a corresponding structure.

A wafer 800 is formed. Wafer 800 may include a substrate 840, one or more first acoustic resonators 842 (and 844) over substrate 840. Wafer 800 may include a piezoelectric layer 846 extending in one or more first acoustic resonators 842 and/or 844. Another initial connection structure 850 may also be formed on substrate 840. In some embodiments, other initial connection structure 850 includes at least one stack structures formed with a plurality of alternating metal layers of high/low acoustic impedances (e.g., W/AlCu). Details of the materials and fabrication of wafer 800 may be referred to the description of second wafer 701 (e.g., FIG. 7D), and are not repeated.

At step 605, a via structure is formed over and conductively connected to the first acoustic resonator. FIG. 8B illustrates a corresponding structure.

A first via structure 854 may be formed over and in contact with first acoustic resonator 842 (or 844). Another first via structure 856 may be formed over and in contact with other initial connection structure 850. A dielectric layer 858 may be formed surrounding first via structure 854, other via structure 856, and first acoustic resonators 842 and/or 844. In some embodiments, the thickness of via structure 854 may be between about 3 μm and about 5 μm. Details of the materials and fabrication of the via structures and dielectric layer 858 may be referred to the description of second wafer 701 (e.g., FIG. 7D), and are not repeated.

At step 607, a second acoustic resonator is formed over and conductively connected to the via structure. FIG. 8C illustrates a corresponding structure.

A second acoustic resonator 804 (and/or 802) may be formed over and conductively connected to via structure 854. Second acoustic resonator 804 (and/or) may be formed over the surface of dielectric layer 858. The reflector structures of second acoustic resonator 804 (and/or 802) may be deposited in contact with via structure 854. In some embodiments, a second initial connection structure is formed over and in contact with via structure 856, forming a connection structure 862. In some embodiments, the second initial connection structure includes one or more stack structures, which are formed in the same fabrication processes that form the reflector structures of second acoustic resonator 804 (and/or 802). The fabrication process to form second acoustic resonator 804 (and/or 802), and connection structure 862 may be referred to the fabrication process of second wafer 701, and the detailed description is not repeated herein.

A cover layer with openings and terminals contacts may then be formed over the monolithic wafer 800. The fabrication process may be referred to that of FIG. 7F, and the detailed description is not repeated herein.

1. A radio frequency (RF) filtering circuit, comprising:
a first acoustic resonator disposed over a substrate;
a second acoustic resonator disposed over the first acoustic resonator; and
a via structure disposed between the first acoustic resonator and the second acoustic resonator, in contact with the first acoustic resonator and the second acoustic resonator,
wherein the first acoustic resonator and the second acoustic resonator are conductively connected to each other through the via structure.

2. The RF filtering circuit of claim 1, wherein:
the first acoustic resonator comprises:
a first piezoelectric layer,
a first electrode disposed over the first piezoelectric layer,
a second electrode disposed under the first piezoelectric layer,
a first insulating layer over the first electrode,
a second insulating layer under the second electrode,
a first reflector structure over the first insulating layer, and
a second reflector structure under the second insulating layer; and
the second acoustic resonator comprises:
a second piezoelectric layer,
a first electrode disposed over the second piezoelectric layer,
a second electrode disposed under the second piezoelectric layer,
a first insulating layer over the first electrode,
a second insulating layer under the second electrode,
a first reflector structure over the first insulating layer, and
a second reflector structure under the second insulating layer.

3. The RF filtering circuit of claim 2, wherein:
the first reflector structure comprises a first conductive bridge structure conductively connected to a peripheral area of the first electrode; and
the second reflector structure comprises a second conductive bridge structure conductively connected to a peripheral area of the second electrode.

4. The RF filtering circuit of claim 3, wherein the first reflector structure and the second reflector structure each comprises a stack of alternating high-acoustic-impedance metal layers and low-acoustic-impedance metal layers.

5. The RF filtering circuit of claim 4, wherein the high-acoustic-impedance metal layers comprise tungsten, and the low-acoustic-impedance metal layers comprise aluminum copper.

6. The RF filtering circuit of claim 2, wherein the via structure is in contact with the second reflector structure of the first acoustic resonator and the first reflector structure of the second acoustic resonator.

7. The RF filtering circuit of claim 6, wherein the via structure is disposed in an insulating spacer between the second reflector structure of the first acoustic resonator and the first reflector structure of the second acoustic resonator, wherein a thickness of the insulating spacer is between about 3 μm and about 5 μm.

8. The RF filtering circuit of claim 1, wherein the via structure comprises copper.

9. The RF filtering circuit of claim 1, wherein a vertical projection of the via structure is overlapped with a vertical projection of at least one of the first acoustic resonator or the second acoustic resonator.

10. The RF filtering circuit of claim 1, wherein a vertical projection of the via structure is located outside a vertical projection of the first acoustic resonator or the second acoustic resonator.

11. The RF filtering circuit of claim 2, wherein the first acoustic resonator and the second acoustic resonator are connected in series.

12. The RF filtering circuit of claim 11, wherein the first acoustic resonator and the second acoustic resonator are each a series resonator.

13. The RF filtering circuit of claim 11, wherein the first acoustic resonator is a series resonator, and the second acoustic resonator is a shunt resonator, the first reflector structure of the second acoustic resonator is connected to ground.

14. The RF filtering circuit of claim 2, further comprising a connection structure in contact with the first reflector structure of the second acoustic resonator and the second reflector of the first acoustic resonator.

15. The RF filtering circuit of claim 14, wherein the first acoustic resonator and the second acoustic resonator are connected in antiparallel, the first reflector structure of the second acoustic resonator is connected to ground.

16. The RF filtering circuit of claim 14, wherein the connection structure comprises
a first stack of alternating high-acoustic-impedance metal layers and low-acoustic-impedance metal layers,
a second stack of the alternating high-acoustic-impedance metal layers and low-acoustic-impedance metal layers over the first stack, and
a second via structure in contact with the first stack and the second stack.

17. The RF filtering circuit of claim 2, further comprising:
a third acoustic resonator on a same level as the first acoustic resonator, wherein the third acoustic resonator comprising a third piezoelectric layer leveling with and in contact with the first piezoelectric layer, and a first reflector structure leveling with and in contact with the first reflector structure of the first acoustic resonator; and
a fourth acoustic resonator on a same level as the second acoustic resonator, wherein the fourth acoustic resonator comprising a fourth piezoelectric layer leveling with and in contact with the second piezoelectric layer, a first reflector structure leveling with and in contact with the first reflector structure of the second acoustic resonator, and a second reflector structure leveling with and in contact with the second reflector structure of the second acoustic resonator,
wherein the first reflector structure of the second acoustic resonator is connected to ground.

18. The RF filtering circuit of claim 17, wherein:
the first acoustic resonator and the third acoustic resonator are series resonators conductively connected in series with each other such that the first electrode of the first acoustic resonator is conductively connected to a first electrode of the third acoustic resonator; and
the second acoustic resonator and the fourth acoustic resonator are shunt resonators conductively connected in parallel with each other between ground and a middle point between the first acoustic resonator and the third acoustic resonator such that the first electrode of the second acoustic resonator is conductively connected to a first electrode of the fourth acoustic resonator, and the second electrode of the second acoustic resonator is conductively connected to a second electrode of the fourth acoustic resonator.

19. A method for forming a radio frequency circuit, comprising:
forming a first wafer comprising a first acoustic resonator over a first substrate and a first initial via structure conductively connected to the first acoustic resonator;
forming a second wafer comprising a second acoustic resonator over a second substrate and a second initial via structure conductively connected to the first acoustic resonator; and
bonding the first wafer and the second wafer in a face-to-face manner such that the first initial via structure is in contact with the second initial via structure to form a via structure.

20. A method for forming a radio frequency circuit, comprising:
forming a first acoustic resonator over a substrate;
forming a via structure over and conductively connected to the first acoustic resonator; and
forming a second acoustic resonator over and conductively connected to the via structure.
